(19) United States
(12) Patent Application Publication
(10) Pub. No.: US 2014/0124755 A1
(43) Pub. Date: May 8, 2014

(54) THIN FILM TRANSISTOR AND METHOD OF MANUFACTURING THE SAME

(71) Applicant: Samsung Display Co., Ltd., Yongin-City (KR)

(72) Inventors: Jung-Hun Lee, Yongin-city (KR); Kyong-Tae Park, Yongin-City (KR)

(21) Appl. No.: 13/954,810

(22) Filed: Jul. 30, 2013

(30) Foreign Application Priority Data
Nov. 6, 2012 (KR) 10-2012-0124939

(51) Int. Cl. H01L 29/786; H01L 29/66

(52) U.S. Cl. CPC H01L 29/78669; H01L 29/6675; H01L 29/78678
USPC 257/40; 438/158

(57) ABSTRACT

A thin film transistor and method of manufacturing the same are disclosed. In one aspect, the thin film transistor includes a gate electrode positioned on a substrate It also includes a gate insulating layer positioned on the gate electrode and a semiconductor positioned on the gate insulating layer. It further includes a source electrode and a drain electrode positioned on the semiconductor, in which the semiconductor has a step at a boundary surface that is in contact with the gate insulating layer.

### CROSS-REFERENCE TO RELATED APPLICATIONS

This application claims priority to and the benefit of Korean Patent Application No. 10-2012-0124939 filed in the Korean Intellectual Property Office on Nov. 6, 2012, the entire contents of which are incorporated herein by reference.

### BACKGROUND

1. Field of the Technology

The described technology relates generally to a thin film transistor, and more particularly, to a thin film transistor including an organic semiconductor, and a method of manufacturing the same.

2. Description of the Related Technology

A thin film transistor (TFT) has been used as a switching and driving element in a flat panel display, such as a liquid crystal display (LCD), an organic light emitting diode (OLED) display, and an electrophoretic display.

The thin film transistor includes a gate electrode connected to a gate line for transmitting a scan signal, a source electrode connected to a data line for transmitting a signal to be applied to a pixel electrode, a drain electrode facing the source electrode, and a semiconductor electrically connected to the source electrode and the drain electrode.

The semiconductor of the thin film transistor is formed of amorphous silicon or polycrystalline silicon. Since the amorphous silicon may be deposited at a low temperature to form a thin film, the amorphous silicon is often used in a display device. In addition, the electrical characteristics of polycrystalline silicon include high electron mobility, high frequency operation, and low leakage current.

However, the amorphous silicon thin film is problematic in forming a large display area because of its low mobility in electric field, and the polycrystalline silicon has a problem in a complex crystallization process.

A solution process has been developed to form a semiconductor using an organic semiconductor that is light, can form a large display area, and can be deposited at a low temperature.

However, the electrical characteristic of the semiconductor formed through the solution process is considerably affected by the size and uniformity of the grain, such as the polycrystalline silicon. That is, as the size and the uniformity of the grain increase, electron mobility is also increased.

### SUMMARY OF CERTAIN INVENTIVE ASPECTS

One inventive aspect is a thin film transistor having an advantage of improving an electrical characteristic by increasing a size of a grain, and a method of manufacturing the same.

Another aspect is a thin film transistor including a gate electrode positioned on a substrate; a gate insulating layer positioned on the gate electrode; a semiconductor positioned on the gate insulating layer; and a source electrode and a drain electrode positioned on the semiconductor, in which the semiconductor has a step at a boundary surface that is in contact with the gate insulating layer.

The thin film transistor may further include a first barrier rib positioned on the gate insulating layer, in which the first barrier rib is positioned on a virtual extending line extending in a width direction of a channel.

The thin film transistor may further include a second barrier rib positioned on the source electrode and the drain electrode.

The gate electrode or the gate insulating layer may have a recess portion or a through-hole.

The recess portion or the through-hole may be positioned outside the channel and positioned on the virtual extending line.

Upper surfaces of the source electrode and the drain electrode may have the same height as that of the first barrier rib or may be positioned so as to protrude from an upper surface of the first barrier rib.

The gate electrode or the gate insulating layer may have a recess portion or a through hole.

The recess portion or the through-hole may be positioned outside the channel and positioned on the virtual extending line.

The gate insulating layer may have a stepwise structure, and the stepwise structure overlaps the semiconductor.

The semiconductor may be formed of an organic semiconductor.

The gate insulating layer may include: a first gate insulating layer formed of a photo resist organic material; and a second gate insulating layer positioned on the first gate insulating layer and formed of an inorganic material, and the second gate insulating layer may be in contact with the semiconductor.

Another exemplary embodiment provides a thin film transistor including: a gate electrode positioned on a substrate; a gate insulating layer positioned on the gate electrode; a semiconductor positioned on the gate insulating layer; and a source electrode and a drain electrode positioned on the semiconductor, in which the gate insulating layer has a first recess portion, and the first recess portion has portions having different depths from an upper surface of the gate insulating layer.

The semiconductor may be filled in the first recess portion.

The semiconductor may have a lower portion having the same shape as that of a bottom of the first recess portion.

A surface of the bottom of the first recess portion may have a stepwise structure.

The thin film transistor may further include a first barrier rib positioned on the gate insulating layer, in which the first barrier rib is positioned on a virtual extending line extending in a width direction of a channel.

The thin film transistor may further include a second barrier rib positioned on the source electrode and the drain electrode.

The gate electrode or the gate insulating layer may have a recess portion or a through-hole.

The recess portion or the through-hole may be positioned outside the channel and positioned on the virtual extending line.

Upper surfaces of the source electrode and the drain electrode may have the same height as that of the first barrier rib or may be positioned so as to protrude from an upper surface of the first barrier rib.

The gate electrode or the gate insulating layer may have a recess portion or a through hole.

The recess portion or the through-hole may be positioned outside the channel and positioned on the virtual extending line.

The gate insulating layer may include: a first gate insulating layer formed of a photo resist organic material; and a second gate insulating layer positioned on the first gate insulating layer and formed of an inorganic material, and the second gate insulating layer may be in contact with the semiconductor.

The semiconductor may be formed of an organic semiconductor.

Yet another exemplary embodiment provides a method of manufacturing a thin film transistor, including: forming a gate electrode on a substrate; forming a gate insulating layer on the gate electrode; forming a recess portion having different depths in the gate insulating layer; forming a source electrode and a drain electrode on the gate insulating layer; and forming a semiconductor by dispensing an solution semiconductor on the recess portion of the gate insulating layer, in which in the dispensing of the solution semiconductor, the solution semiconductor is dispensed at a portion at which the depth of the recess portion is small to flow in a direction in which the depth of the recess portion increases.

The forming of the recess portion may include: forming a photo resist pattern having a first portion and a second portion having different thicknesses on the gate insulating layer; forming a preliminary recess portion by etching the gate insulating layer by using the photo resist pattern as a mask; and removing the first portion of the photo resist pattern and then etching the gate insulating layer by using the second portion as a mask.

When the thin film transistor is formed by the method according to the present invention, a size of a crystal may be easily increased.

Further, it is possible to easily form a thin film transistor, implement a large thin film transistor, and improve productivity by using a solution semiconductor.

### BRIEF DESCRIPTION OF THE DRAWINGS

FIG. 1 is a top plan view of a thin film transistor according to an embodiment.

FIG. 2 is a cross-sectional view taken along line II-II of FIG. 1.

FIG. 3 is a cross-sectional view taken along line III-III of FIG. 1.

FIGS. 4 to 8 are cross-sectional views for describing a method of manufacturing the thin film transistor of the present invention, and are cross-sectional views taken along line III-III of FIG. 1.

FIG. 9 is a cross-sectional view of a thin film transistor according to an embodiment.

FIGS. 10 to 12 are cross-sectional views of an intermediate step of manufacturing the thin film transistor according to the second exemplary embodiment.

FIGS. 13 and 14 are cross-sectional views of a thin film transistor according to an embodiment.

FIG. 15 is a top plan view of a thin film transistor according to an embodiment.

FIG. 16 is a cross-sectional view taken along line XVI-XVI of FIG. 15.

FIG. 17 is a cross-sectional view taken along line XVII-XVII of FIG. 15.

FIG. 18 is a cross-sectional view of a thin film transistor according to an embodiment.

FIGS. 19 and 20 are cross-sectional views of a thin film transistor according to an embodiment.

### DETAILED DESCRIPTION OF CERTAIN INVENTIVE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In the drawings, the thickness of layers, films, panels, regions, etc., are exaggerated for clarity. The same reference numerals designate the same or like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Hereinafter, a thin film transistor according to an embodiment will be described with reference to the accompanying drawings.

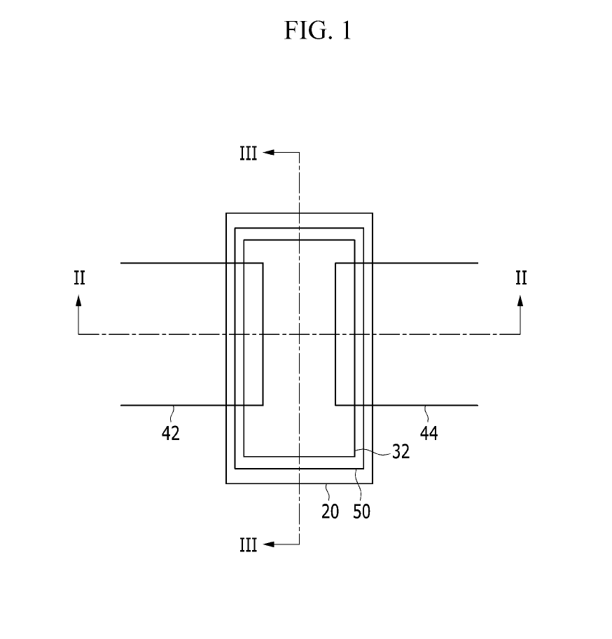

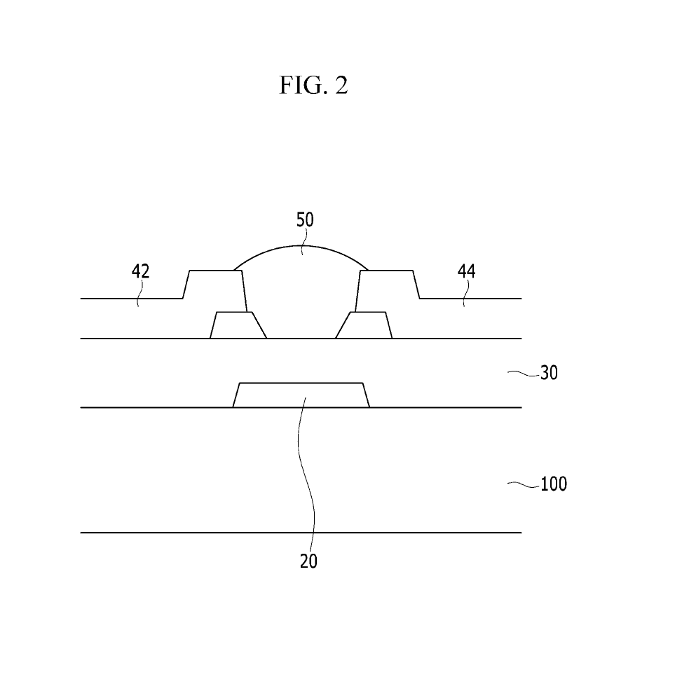

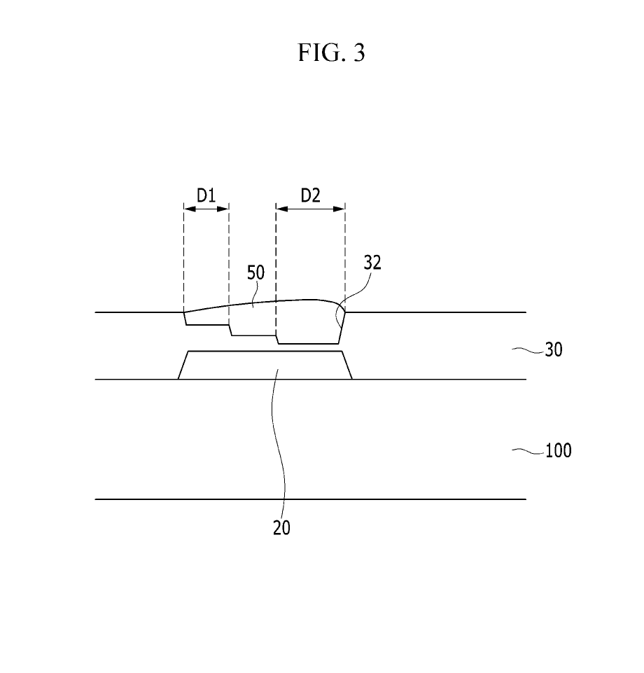

FIG. 1 is a top plan view of a thin film transistor according to a first exemplary embodiment, FIG. 2 is a cross-sectional view taken along line II-II of FIG. 1, and FIG. 3 is a cross-sectional view taken along line III-III of FIG. 1.

As illustrated in FIGS. 1 to 3, a thin film transistor Q according to an embodiment includes a gate electrode 20 positioned on a substrate 100, a gate insulating layer 30 positioned on the gate electrode 20, a source electrode 42 and a drain electrode 44 positioned on the gate insulating layer 30, and a semiconductor 50 positioned on the gate insulating layer 30 and overlapping the source electrode 42 and the drain electrode 44.

The substrate 100 may be formed of any material suitable for forming the thin film transistor, such as glass, metal, or a flexible polymer material.

The gate electrode 20 may be formed as a single layer or a multilayer and may be formed of polysilicon, metal, such as copper, aluminum, tungsten, and titanium, or an alloy thereof.

The gate insulating layer 30 covers the gate electrode 20, and has a first recess portion 32 overlapping the gate electrode 20. A bottom of the first recess portion 32 may have a step structure. Accordingly, the gate insulating layer 30 has portions having different depths from an upper surface thereof.

In FIGS. 2 and 3, the gate insulating layer 30 is formed so as to have three different depths, but may be formed so as to have more different depths by forming two steps or three or more steps. The number of steps may vary according to a size of the semiconductor and a size of a channel.

When the gate insulating layer 30 is formed so as to have three depths, the shallowest portion, an intermediate portion, and the deepest portion are sequentially positioned in the first recess portion 32 in order. Accordingly, the first recess portion 32 may be gradually deep or shallow.

The gate insulating layer 30 may be formed as a single layer or a multilayer and may be formed of an inorganic layer, such as silicon nitride or silicon oxide, or an organic material in which a photosensitizer is added to a material, such as poly vinyl alcohol (PVA).

The source electrode 42 and the drain electrode 44 face each other while overlapping the semiconductor 50. The source electrode 42 and the drain electrode 44 may also be formed as a single layer or a multilayer formed of the same metal as that of the gate electrode 20 or an alloy thereof.

The semiconductor 50 is formed of an organic semiconductor made by a solution process, and may be formed as a material including at least one of a 2,9-dialkyl-dinaphtho[2,3-b:2′,3′-f]thieno[3,2-b]thiophenes(Cn-DNTT) derivative, a derivative of [1]benzothieno[3,2-b]benzothiophen(BTBT), TIPS-pentacene, TES-ADT and a derivative thereof, a perylene derivative, TCNQ, F4-TCNQ, F4-TCNQ, rubrenes, pentacene, p3HT, pBTTT, and pDA2T-C16. For example, the 2,9-dialkyl-dinaphtho[2,3-b:2′,3′-f]thieno[3,2-b]thiophenes(Cn-DNTT) derivative and the derivative of [1]benzothieno[3,2-b]benzothiophen(BTBT) may be formed of C₁₀-DNTT or C₈-BTBT.

In some embodiments, a solvent may be acetone, methanol, ethanol, methanol, IPA, benzene, toluene, xylene, hexane, butyl acetate, and butanol.

The semiconductor 50 fills the first recess portion 32 and may have a lower portion with the same shape as that of the bottom of the first recess portion 32. That is, the semiconductor 50 may have a step at a boundary surface that is in contact with the gate insulating layer 30.

The first recess portion 32 has different portions with different depths from the upper surface of the gate insulating layer 30. Accordingly, the semiconductor 50 has a shape of which a thickness is larger as being close from a portion D1 of the first recess portion having the smallest depth to a portion D2 of the first recess portion 32 having the largest depth. The reason is that a crystal grows from the portion D1 of the first recess portion 32 having the smallest depth to the portion D2 of the first recess portion 32 having the largest depth. The semiconductor 50 may be a single crystal or a multi-crystal having the shape of the first recess portion, but one crystal has a shape of which a size is increased from the shallow portion of the first recess portion 32 to the deep portion of the first recess portion 32.

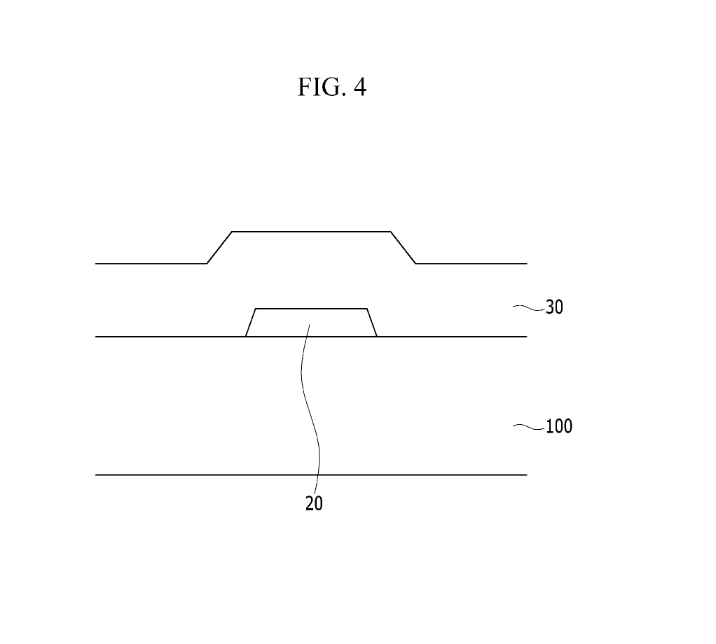

The method of manufacturing the thin film transistor will be described in detail with reference to FIGS. 4 to 9.

FIGS. 4 to 8 are cross-sectional views for describing the method of manufacturing the thin film transistor and are cross-sectional views taken along line III-III of FIG. 1.

As illustrated in FIG. 4, the gate electrode 20 is formed by forming a metal layer on the substrate 100 and patterning the metal layer.

Then, the gate insulating layer 30 is formed on the gate electrode 20.

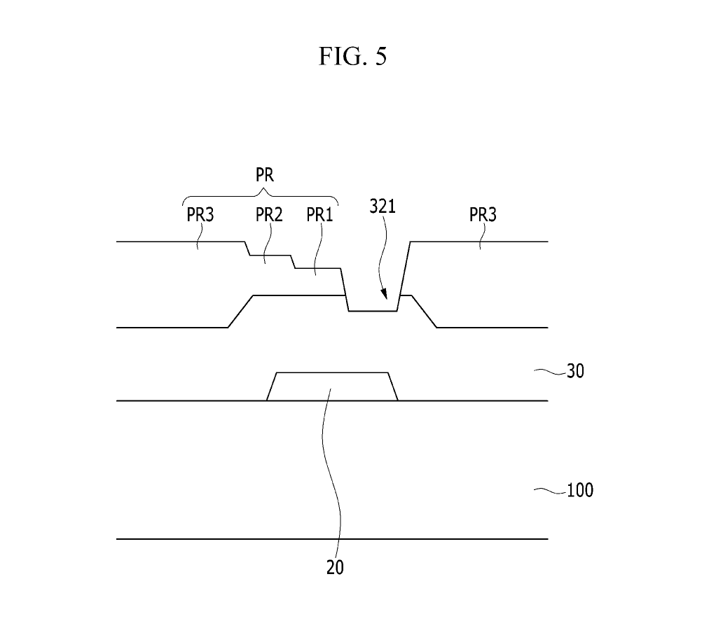

Next, as illustrated in FIG. 5, a photo resist pattern PR having different thicknesses is formed on the gate insulating layer 30.

Hereinafter, the first recess portion having three portions with different depths will be described as an example.

The photo resist pattern PR is formed by applying a photo resist material and then exposing and developing the photo resist material. The photo resist pattern PR includes a first photo resist pattern PR1, a second photo resist pattern PR2, and a third photo resist pattern PR3 having different thicknesses. The thicknesses of the first photo resist pattern PR1, the second photo resist pattern PR2, and the third photo resist pattern PR3 may be in an increasing order of the first photo resist pattern PR1, the second photo resist pattern PR2, and the third photo resist pattern PR3.

As described, there may be several methods of differently forming the thickness of the photo resist pattern PR according to a position. One example thereof includes a method of forming a plurality of semi-transparent area having different transparency degrees, a transparent area, and a light blocking area in an exposure mask. A slit pattern, a lattice pattern, or a thin film having intermediate transmittance or an intermediate thickness is formed in the semi-transparent area. When the slit pattern is used, a width of the slit or an interval between the slits may be smaller than the resolution of an exposer used in a photolithography process.

Then, a first preliminary recess portion 321 is formed by etching the gate insulating layer 30 by using the photo resist pattern PR as a mask. A depth of the first preliminary recess portion 321 may be adjusted by an etching time.

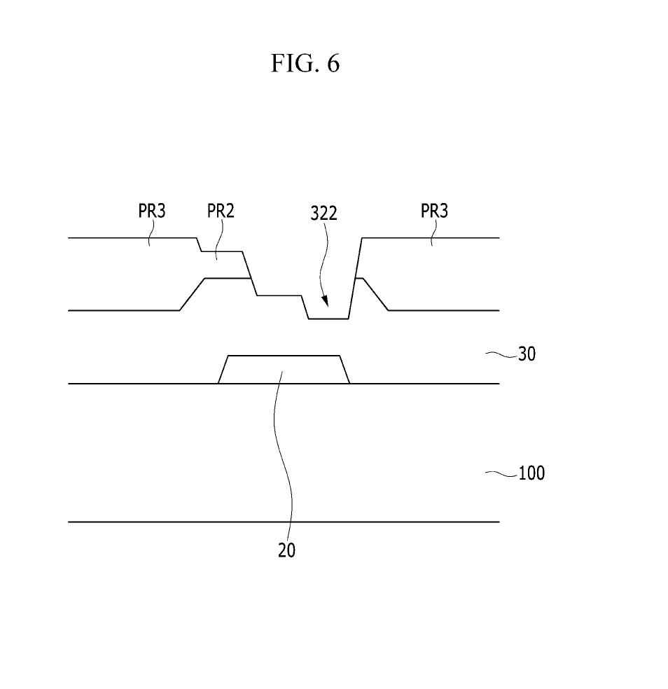

Next, as illustrated in FIG. 6, after the first photo resist pattern PR1 is removed, a second preliminary recess portion 322 is formed by etching the gate insulating layer 30 by using the second photo resist pattern PR2 and the third photo resist pattern PR3 as a mask.

In this case, an upper portion of the second photo resist pattern PR2 is also removed by a thickness of the first photo resist pattern PR1 together with the first photo resist pattern PR1, so that a thickness thereof may be decreased.

The gate insulating layer exposed by the first preliminary recess portion is removed together with the gate insulating layer at a portion at which the first photo resist layer PR1 is removed, so that the depth of the first recess portion is further increased.

Accordingly, the second preliminary recess portion 322 includes two portions having different depths including the portion at which the first photo resist pattern PR1 is removed and a portion at which the gate insulating layer exposed by the first preliminary recess portion 321 is removed.

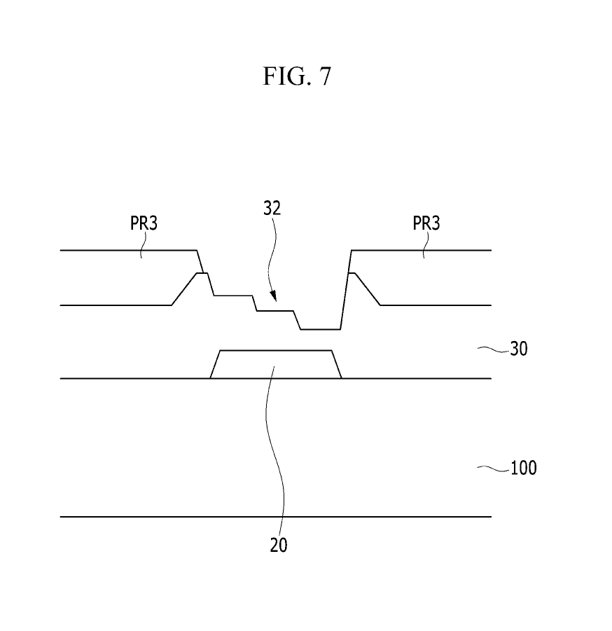

Next, as illustrated in FIG. 7, after the second photo resist pattern PR2 is removed, and then the first recess portion 32 is completed by etching the gate insulating layer 30 by using the third photo resist pattern PR3 as a mask.

In this case, an upper portion of the third photo resist pattern PR3 is removed by a thickness of the second photo resist pattern together with the second photo resist pattern PR2, so that the thickness of the third photo resist pattern PR3 may be decreased.

The gate insulating layer exposed by the second preliminary recess portion is removed together with the gate insulating layer at a portion at which the second photo resist layer PR2 is removed, so that the depth of the second preliminary recess portion is further increased.

Accordingly, the first recess portion 32 includes three portions having different depths including the portion at which the second photo resist pattern is removed and the portion at which the gate insulating layer exposed by the second preliminary recess portion is removed.

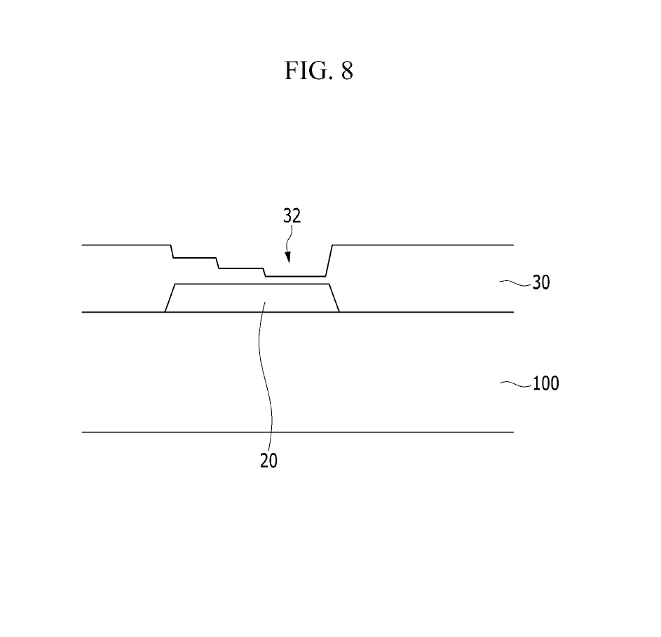

Next, as illustrated in FIG. 8, the source electrode 42 and the drain electrode 44 are formed by forming a metal layer on the gate insulating layer 30 and patterning the metal layer after removing the third photo resist pattern. The source electrode 42 and the drain electrode 44 are formed so as to face each other with the first recess portion 32 interposed therebetween.

Next, as illustrated in FIGS. 2 and 3, the semiconductor 50 is formed by dispensing a solution-type organic semiconductor using an inkjet method in the first recess portion 32 and filling the first recess portion 32 with the dispensed solution-type organic semiconductor.

The organic semiconductor solution is dispensed in the portion D1 of the first recess portion 32 having the smallest depth and flows down along the step-like structure formed at the bottom of the first recess portion 32 to be transmitted to the portion D2 having the largest depth of the first recess portion 32.

In this case, the solution dispensed in the first recess portion 32 is formed as a crystal while the solvent is evaporated, and the initially formed crystal becomes a seed. The number of formed seeds may be one, but a plurality of seeds may be formed. Further, when the organic semiconductor solution is dispensed until the first recess portion 32 is completely filled, the organic semiconductor solution flows down along the seed, so that the crystal of the semiconductor grows while being close to the portion D2 of the first recess portion 32 having the largest depth based on the seed.

Since the crystal grows while the organic semiconductor solution flows down and the solvent is evaporated, when a flow speed of the organic semiconductor solution is adjusted, a semiconductor having a desired size may be easily formed. The flow speed of the organic semiconductor solution may be changed according to an evaporation speed of the solvent, a gradient according to the number of steps included in the step-type structure, and surface energy.

The organic semiconductor solution may be formed of a material including at least one of a 2,9-dialkyl-dinaphtho[2,3-b:2′,3′-f]thieno[3,2-b]thiophenes(Cn-DNTT) derivative, a derivative of [1]benzothieno[3,2-b]benzothiophen(BTBT), TIPS-pentacene, TES-ADT and a derivative thereof, a perylene derivative, TCNQ, F4-TCNQ, F4-TCNQ, p3HT, pBTTT, and pDA2T-C16. For example, the 2,9-dialkyl-dinaphtho[2,3-b:2′,3′-f]thieno[3,2-b]thiophenes(Cn-DNTT) derivative and the derivative of [1]benzothieno[3,2-b]benzothiophen(BTBT) may be formed of C₁₀-DNTT or C₈-BTBT.

Further, the solvent may be acetone, methanol, ethanol, methanol, IPA, benzene, toluene, xylene, hexane, butyl acetate, and butanol.

A speed of the surface energy may be adjusted by using oxygen plasma, an octadecyltrichlorosilane (OTS) process, a hexamethyldisilazane (HMDS) process, and a Pentafluorobenzenethiol (PFBT) process.

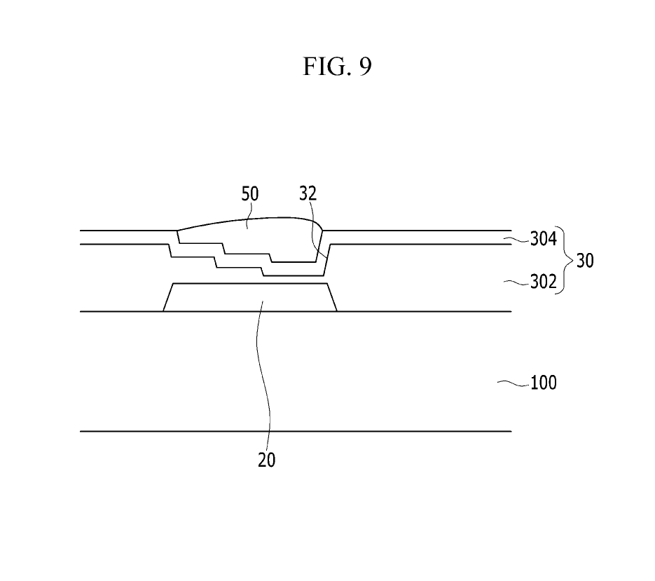

FIG. 9 is a cross-sectional view of a thin film transistor according to an embodiment.

The embodiment illustrated in FIG. 9 is substantially the same as the first exemplary embodiment illustrated in FIGS. 1 to 3, except for the gate insulating layer 30, thus the repeated description is omitted.

As illustrated in FIG. 9, the gate insulating layer 30 according to an embodiment includes a first gate insulating layer 302 formed of a photo resist organic material and a second gate insulating layer 304 formed of an inorganic layer, such as silicon oxide or silicon nitride.

As described above, when the gate insulating layer 30 is formed of the first gate insulating layer 302 and the second gate insulating layer 304, the first recess portion having portions with different depths may be easily formed.

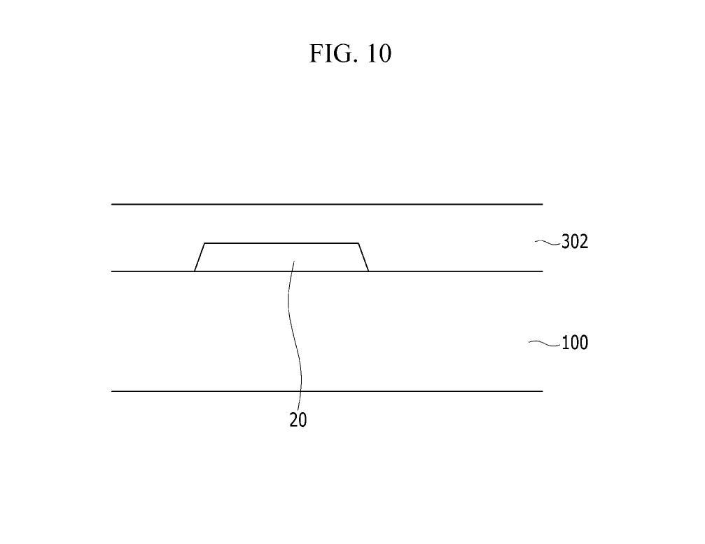

Then, a method of manufacturing the thin film transistor according to an embodiment will be described in detail with reference to FIGS. 10 to 12 together with the aforementioned FIGS. 8 and 9.

FIGS. 10 to 12 are cross-sectional views of an intermediate step of manufacturing the thin film transistor according to an embodiment.

First, as illustrated in FIG. 10, the gate electrode 20 is formed by forming a metal layer on the substrate 100 and patterning the metal layer.

Then, the first gate insulating layer 302 is formed on the gate electrode 20. The first gate insulating layer 302 may be formed of an organic material.

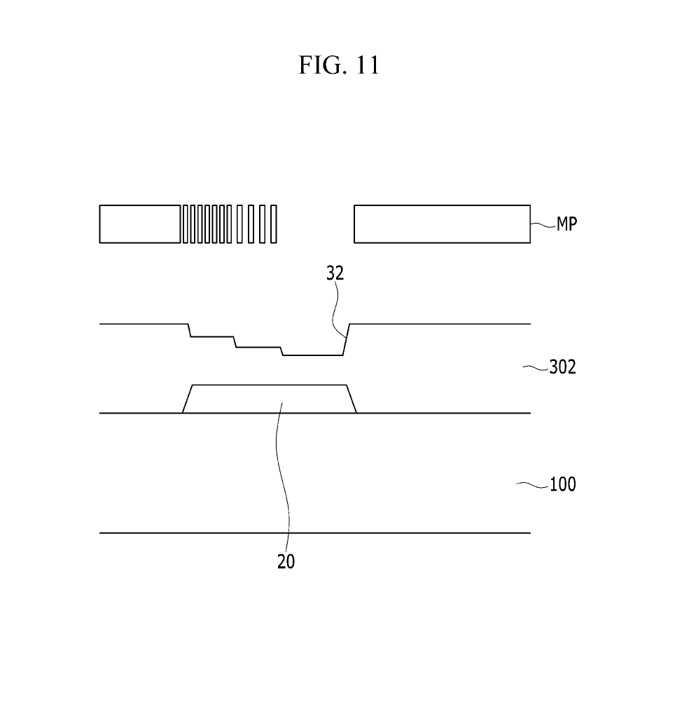

Next, as illustrated in FIG. 11, the first recess portion 32 having different depths is formed by exposing and developing the first gate insulating layer 302.

In this case, the exposure mask MP exposes a plurality of semi-transparent areas having different transparency degrees, a transparent area, and a light blocking area. A thin film having intermediate transmissivity or an intermediate thickness may be included in the semi-transparent area. When the slit pattern is used, a width of the slit or an interval between the slits may be smaller than resolution of an exposer used in a photolithography process.

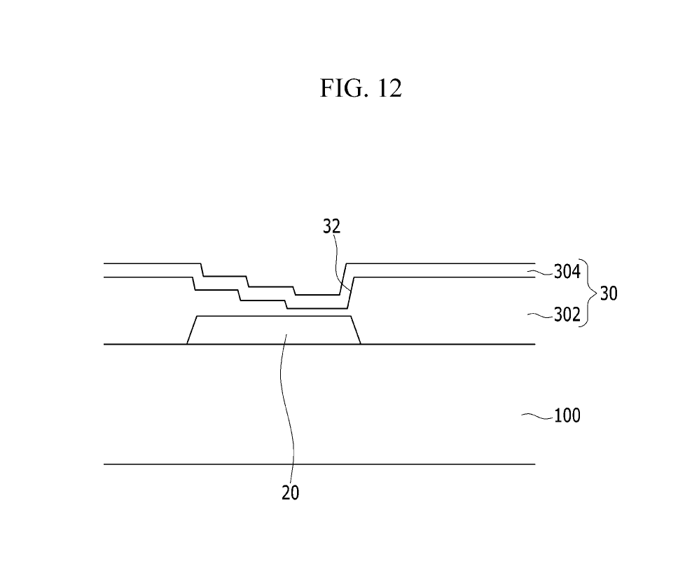

Next, as illustrated in FIG. 12, the gate insulating layer 30 is completed by forming the second gate insulating layer 304 on the first gate insulating layer 302. The second gate insulating layer 304 may be formed of silicon nitride.

A thin film is formed along a shape of the first gate insulating layer 302, so that the second gate insulating layer 304 is directly formed according to the shape of the first recess portion 32 of the first gate insulating layer 302.

As described above, when the first gate insulating layer is formed of the photo resist organic material, the first recess portion 32 having different depths may be formed in the gate insulating layer only by exposure and development process without repeatedly etching the gate insulating layer by using the photo resist pattern as illustrated in FIGS. 5 to 7.

Further, the second gate insulating layer 304 is used for improving an interface characteristic between the semiconductor and the gate insulating layer. Accordingly, when the first gate insulating layer is formed of a material, such as poly vinyl alcohol containing photo resist additives suitable as the gate insulating layer, the second gate insulating layer 304 may be omitted.

Next, as illustrated in FIG. 8, the source electrode 42 and the drain electrode 44 are formed by forming a metal layer on the gate insulating layer 30 and patterning the metal layer.

Next, as illustrated in FIG. 9, the semiconductor 50 is formed by dispensing a solution-type organic semiconductor using an inkjet method in the first recess portion 32 and filling the first recess portion 32 with the dispensed solution-type organic semiconductor.

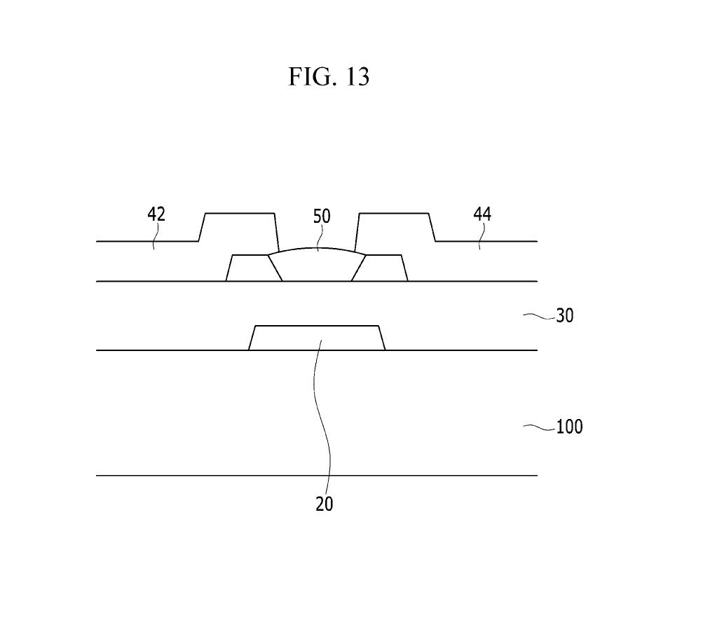

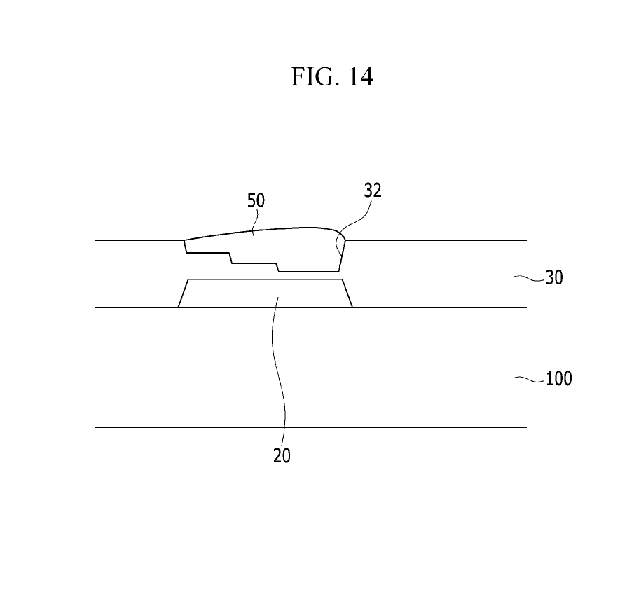

FIGS. 13 and 14 are cross-sectional views of a thin film transistor according to an embodiment.

The embodiment illustrated in FIGS. 13 and 14 is substantially the same as the embodiment illustrated in FIGS. 1 to 3, except for positions of the source electrode 42, the drain electrode 44, and the semiconductor 50, thus the repeated description is omitted.

As illustrated in FIGS. 13 and 14, in the thin film transistor according to an embodiment, the semiconductor 50 is positioned at the first recess portion 32 of the gate insulating layer 30, and the source electrode 42 and the drain electrode 44 are positioned on the semiconductor 50.

The semiconductor 50 is formed before the forming of the source electrode and the drain electrode as illustrated in FIGS. 13 and 14, the patterning is performed so that the semiconductor 50 overlaps the source electrode 42 and the drain electrode 44.

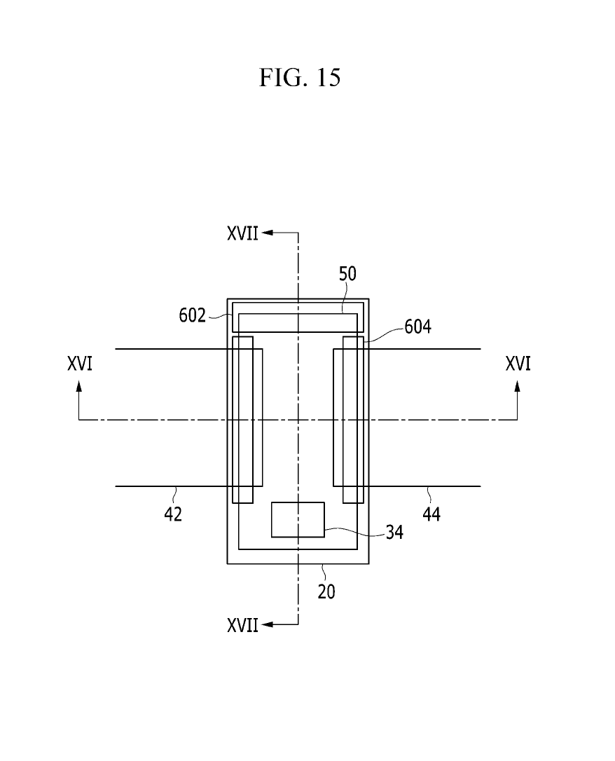

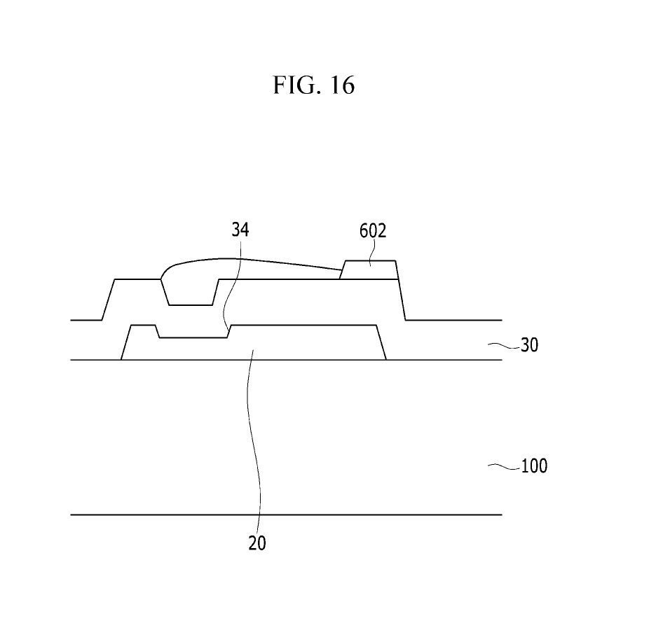

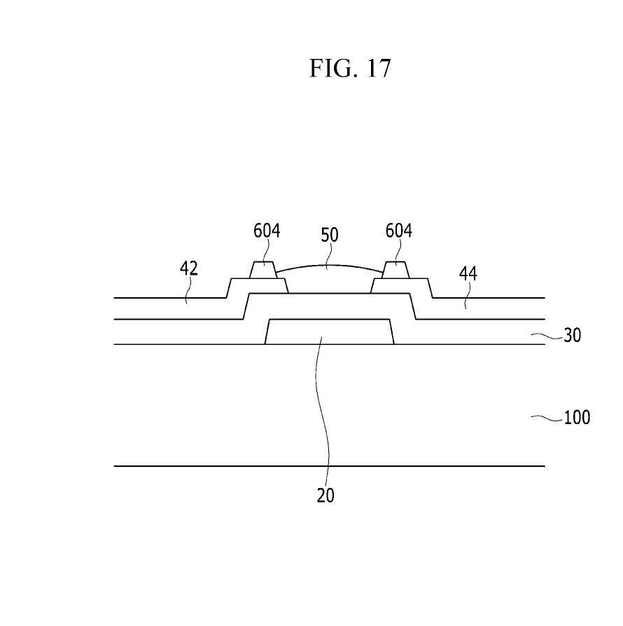

FIG. 15 is a top plan view of a thin film transistor according to an embodiment, FIG. 16 is a cross-sectional view taken along line XVI-XVI of FIG. 15, and FIG. 17 is a cross-sectional view taken along line XVII-XVII of FIG. 15.

The embodiment illustrated in FIG. 15 is substantially the same as the embodiment illustrated in FIGS. 1 to 3, except for the gate insulating layer 30 and barrier ribs 60, thus the repeated description is omitted and only a different part is described in detail.

As illustrated in FIGS. 15 to 17, the thin film transistor according to the fourth exemplary embodiment of the includes the gate electrode 20, the gate insulating layer 30 positioned on the gate electrode 20, the source electrode 42 and the drain electrode 44 positioned on the gate insulating layer, barrier ribs 60 positioned on the source electrode 42 and the drain electrode 44, and the semiconductor 50 positioned on the gate insulating layer 30 exposed between the barrier ribs 60.

The gate electrode 20 has a second recess portion 34. The second recess portion 34 is formed at an area except for a space between the source electrode 42 and the drain electrode 44 at which the channel of the thin film transistor is formed.

The second recess portion 34 may be formed by removing the gate electrode 20 from an upper surface of the gate electrode 20 by a predetermined depth, or may be formed in a through-hole shape passing through the gate electrode 20.

In the meantime, the barrier ribs 60 includes a first barrier rib 602 positioned on a virtual extending line connecting the second recess portion 34 and the channel and a second barrier rib 604 positioned on the source electrode 42 and the drain electrode 44.

The barrier rib 60 and the second recess portion 34 include a step similar to the embodiment illustrated in FIG. 1 so that a solution may flow. In this case, the second barrier rib 604 prevents the organic semiconductor solution from overflowing to an area other than the channel.

That is, when the organic semiconductor solution is dispensed on the first barrier rib 602, a seed is formed while the organic semiconductor solution is dried, and then a crystal grows while the organic semiconductor solution flows in the second recess portion 34 by passing the second barrier rib 604 serving as the channel.

The remaining solution failed to be crystallized is collected in the second recess portion 34 while passing the space between the second barrier ribs 604. In this case, the second recess portion 34 is positioned outside the channel, so that it is possible to prevent the solution of the second recess portion 34 from exerting influence on a crystal positioned in the channel again during the drying.

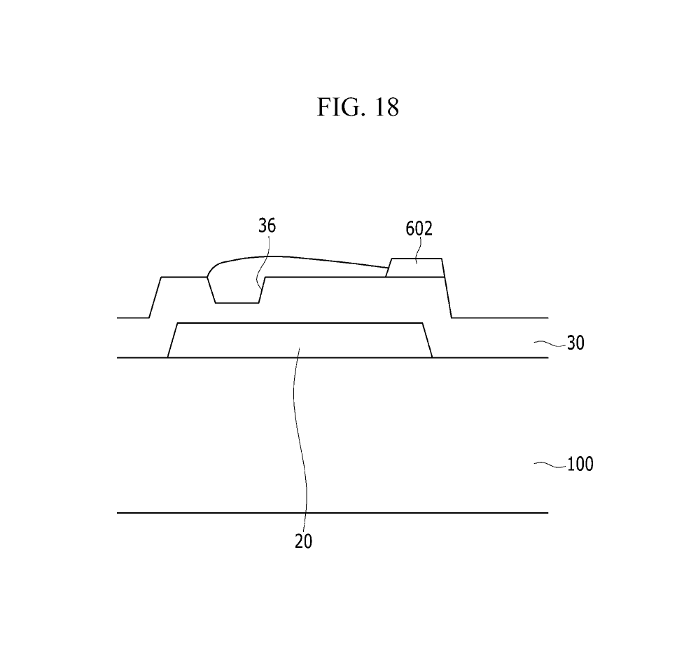

FIG. 18 is a cross-sectional view of a thin film transistor according to an embodiment.

The embodiment illustrated in FIG. 18 is substantially the same as the embodiment illustrated in FIGS. 15 to 17, except for the position of the recess portion, thus the repeated description is omitted and only a different part is described in detail.

As illustrated in FIG. 18, in the thin film transistor, the gate insulating layer 30 has a third recess portion 36.

The third recess portion 36 may be formed by removing the gate insulating layer 30 from an upper surface of the gate insulating layer 30 by a predetermined depth, or may be formed in a through-hole shape passing through the gate insulating layer 30.

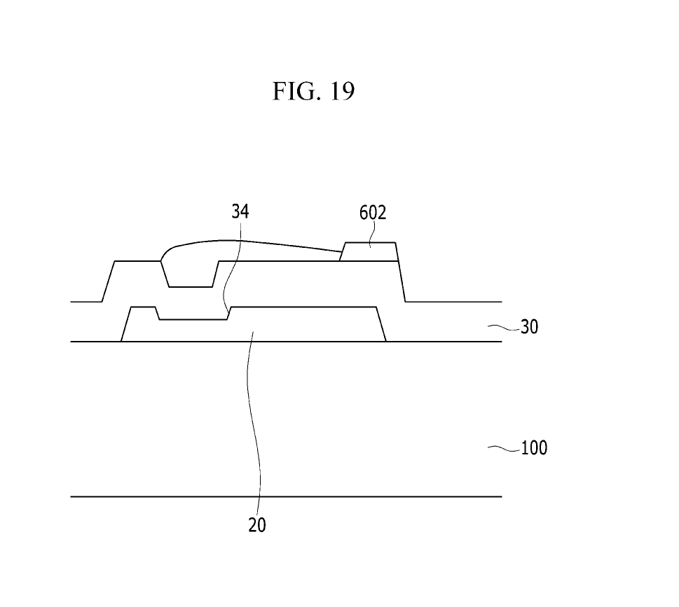

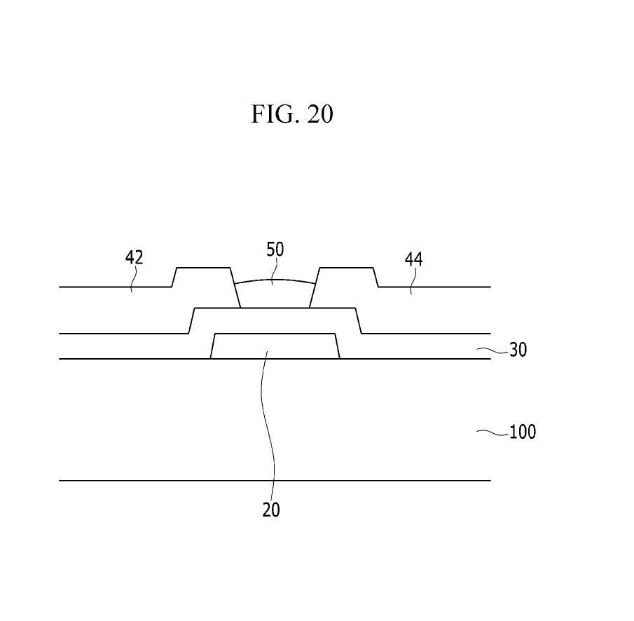

FIGS. 19 and 20 are cross-sectional views of a thin film transistor according to an embodiment.

The embodiment illustrated in FIGS. 19 and 20 is substantially the same as the embodiment illustrated in FIGS. 15 to 17, except for the barrier ribs 60, thus the repeated description is omitted and only a different part is described in detail.

As illustrated in FIGS. 19 and 20, the thin film transistor includes only the first barrier rib 602 positioned on a virtual extending line connecting the second recess portion 34 and the channel.

Then, the source electrode 42 and the drain electrode 44 are formed to be thicker than the source electrode and the drain electrode of the embodiment illustrated in FIGS. 15 to 17. Upper surfaces of the source electrode 42 and the drain electrode 44 may be positioned at the same height of the upper surface of the first barrier rib 602 or protrude from the upper surface of the first barrier rib 602.

As described above, when the source electrode 42 and the drain electrode 44 are formed to be thick, the second barrier rib may not be additionally formed.

In some embodiments, the second barrier rib may not be formed when the source electrode and the drain electrode are too thick (not illustrated).

The above embodiments are presented for illustrative purposes only, and are not intended to define meanings or limit the scope of the present invention as set forth in the following claims. Those skilled in the art will understand that various modifications and equivalent embodiments of the present invention are possible without departing from the spirit and scope of the present invention defined by the appended claims.

What is claimed is:

1. A thin film transistor, comprising
a gate electrode positioned on a substrate;
a gate insulating layer positioned on the gate electrode;
a semiconductor positioned on the gate insulating layer; and
a source electrode and a drain electrode positioned on the semiconductor, wherein the semiconductor has a step at a boundary surface that is in contact with the gate insulating layer.

2. The thin film transistor of claim 1, further comprising a first barrier rib positioned on the gate insulating layer, wherein the first barrier rib is positioned on a virtual extending line extending in a widthwise direction of a channel.

3. The thin film transistor of claim 2, further comprising
a second barrier rib positioned on the source electrode and the drain electrode.

4. The thin film transistor of claim 3, wherein
the gate electrode or the gate insulating layer has a recess portion or a through-hole.

5. The thin film transistor of claim 4, wherein
the recess portion or the through-hole is positioned outside the channel and on the virtual extending line.

6. The thin film transistor of claim 2, wherein:
the source electrode and the drain electrode are positioned to be at the same height as or higher than the first barrier rib.

7. The thin film transistor of claim 6, wherein:
the gate electrode or the gate insulating layer has a recess portion or a through hole.

8. The thin film transistor of claim 7, wherein
the recess portion or the through-hole is positioned outside the channel and on the virtual extending line.

9. The thin film transistor of claim 1, wherein
the gate insulating layer has a step-like structure, and the step-like structure overlaps the semiconductor.

10. The thin film transistor of claim 1, wherein
the semiconductor is formed of an organic semiconductor.

11. The thin film transistor of claim 1, wherein
the gate insulating layer comprises: a first gate insulating layer formed of a photo resist organic material; and
a second gate insulating layer positioned on the first gate insulating layer and formed of an inorganic material, and
the second gate insulating layer is in contact with the semiconductor.

12. A thin film transistor, comprising:
a gate electrode positioned on a substrate;
a gate insulating layer positioned on the gate electrode;
a semiconductor positioned on the gate insulating layer; and
a source electrode and a drain electrode positioned on the semiconductor,
wherein the gate insulating layer has a first recess portion, and the first recess portion has portions with different depths from an upper surface of the gate insulating layer.

13. The thin film transistor of claim 12, wherein:
the semiconductor is filled in the first recess portion.

14. The thin film transistor of claim 12, wherein:
the semiconductor has a lower portion having the same shape as that of a bottom of the first recess portion.

15. The thin film transistor of claim 12, wherein:
a surface of the bottom of the first recess portion has a step-like structure.

16. The thin film transistor of claim 12, further comprising
a first barrier rib positioned on the gate insulating layer,
wherein the first barrier rib is positioned on a virtual extending line extending in a widthwise direction of a channel.

17. The thin film transistor of claim 16, further comprising
a second barrier rib positioned on the source electrode and the drain electrode.

18. The thin film transistor of claim 17, wherein:
the gate electrode or the gate insulating layer has a recess portion or a through-hole.

19. The thin film transistor of claim 18, wherein:
the recess portion or the through-hole is positioned outside the channel and on the virtual extending line.

20. The thin film transistor of claim 16, wherein:
the source electrode and the drain electrode are positioned to be at the same height or higher than the first barrier rib.

21. The thin film transistor of claim 20, wherein
the gate electrode or the gate insulating layer has a recess portion or a through hole.

22. The thin film transistor of claim 21, wherein:
the recess portion or the through-hole is positioned outside the channel and on the virtual extending line.

23. The thin film transistor of claim 12, wherein
the gate insulating layer comprises a first gate insulating layer formed of a photo resist organic material; and
a second gate insulating layer positioned on the first gate insulating layer and formed of an inorganic material, and
the second gate insulating layer is in contact with the semiconductor.

24. The thin film transistor of claim 12, wherein
the semiconductor is formed of an organic semiconductor.

25. A method of manufacturing a thin film transistor, comprising:
forming a gate electrode on a substrate;
forming a gate insulating layer on the gate electrode;
forming a recess portion having different depths in the gate insulating layer;
forming a source electrode and a drain electrode on the gate insulating layer; and
forming a semiconductor by dispensing an solution semiconductor on the recess portion of the gate insulating layer, wherein the solution semiconductor is dispensed at a portion at which the depth of the recess portion is small so as to flow in a direction in which the depth of the recess portion increases.

26. The method of claim 25, wherein
forming of the recess portion comprises
forming a photo resist pattern having a first portion and a second portion having different thicknesses on the gate insulating layer;
forming a preliminary recess portion by etching the gate insulating layer using the photo resist pattern as a mask; and
removing the first portion of the photo resist pattern and then etching the gate insulating layer using the second portion as a mask.
